(19) United States
(12) Patent Application Publication
(10) Pub. No.: US 2006/0252267 A1
(43) Pub. Date: Nov. 9, 2006

(54) Topology-selective oxide CMP

(76) Inventors: Wai Shu Wang, Hsinchu (TW); Yung-Tai Hung, Hsinchu (TW); Yun Chi Yang, Hsinchu (TW); Hsueh Hao Shih, Hsinchu (TW); Kung Chao Chen, Hsinchu (TW)

Correspondence Address: KNOBBE MARTENS OLSON & BEAR LLP, 2040 MAIN STREET, FOURTEENTH FLOOR, IRVINE, CA, 92614, US

(21) Appl. No.: 11/125,303

(22) Filed: May 6, 2005

(51) Int. Cl. H01L 21/461; C03C 15/00; B44C 1/22

(52) U.S. Cl. 438/692; 438/734; 216/88

(57) ABSTRACT

A method of performing chemical mechanical polishing (CMP) is described herein. By way of example, substantially undiluted slurry is applied to a polishing pad. A first CMP process is performed using the substantially undiluted slurry on a semiconductor wafer applying a first amount of pressure. The first CMP process is terminated. Diluted slurry is applied to the polishing pad. A second CMP process is performed using the diluted slurry on the semiconductor wafer while applying a second amount of pressure, wherein the second amount of pressure is less than the first amount of pressure. The second CMP process is terminated.

### BACKGROUND OF THE INVENTION

1. Field of the Invention

The present invention relates to chemical mechanical polishing, and in particular to performing chemical mechanical polishing using slurries.

2. Description of the Related Art

Chemical mechanical polishing (CMP) is conventionally used to achieve global planarization. For example, CMP is often used to reduce the effects of wafer thickness variations and surface topography, such as protrusions. CMP can be used to planarize or smooth microelectronic wafer-based semiconductor devices, including metal films and dielectrics therein. CMP is often performed using slurries. The slurry can include both abrasive particles for mechanical polishing and a chemical solution, such as an oxidizer, for chemical polishing. One example slurry uses ceria or CeO₂ abrasive, which is suitable for polymer and metal polishing.

In particular, the CMP process can be performed by disposing an appropriate slurry between the surface to be polished and a polishing pad. The polishing pad is then spun and applied with an appropriate amount of pressure to smooth or remove undesired irregularities and protrusions. The oxidizer can also remove or dissolve the abraded material.

However, conventional CMP processes are often not fully suitable for multi-chamber CVD (chemical vapor deposition) use. For example, some multi-chamber CVD systems provide poor deposition uniformity and may polish edges faster than other areas. Further, many conventional SiO₂ slurries are not topology sensitive. In addition, using conventional CMP, the post CMP within wafer (WIW) may not be sufficiently uniform resulting in a higher than desired device defect rate. Further, the amount of slurry needed and the polishing time may be greater than desired. FIG. 1A illustrates a cross-section of an example wafer wherein the STI (shallow trench isolation) CMP relies on a stop by film selectivity.

### SUMMARY OF THE INVENTION

The present invention relates to chemical mechanical polishing (CMP) using slurries with different abrasive concentrations.

In one example embodiment, a two-step CMP process utilizes a relatively high down force, low topology selectivity CMP process to remove protrusions. By way of example, a substantially undiluted slurry can be used in conjunction with the high down force CMP. Next, a relatively low down force, high topology selectivity CMP process is performed. By way of example, a diluted slurry can be used in conjunction with the low down force CMP. The low topology selectivity CMP is used to remove protrusions, while the high topology selectivity CMP is used to achieve a desired WIW (With In Wafer) uniformity.

One embodiment provides a method of performing chemical mechanical polishing (CMP), the method comprising: applying a substantially undiluted slurry to a polishing pad; performing a first CMP process with the substantially undiluted slurry on a semiconductor wafer using a first amount of pressure; terminating the first CMP process; applying a diluted slurry to the polishing pad; performing a second CMP process with the diluted slurry on the semiconductor wafer using a second amount of pressure, wherein the second amount of pressure is less than the first amount of pressure; and terminating the second CMP process.

Another embodiment provides a method of performing chemical mechanical polishing (CMP), the method comprising: providing a semiconductor wafer having a first film; performing a first CMP process on a semiconductor wafer first film using a first slurry having a first abrasive concentration and applying first amount of pressure; and performing a second CMP process on the semiconductor wafer first film using a second slurry having a second abrasive concentration no greater than 70% of the first concentration, and applying a second amount of pressure, wherein the second amount of pressure is less than the first amount of pressure.

### BRIEF DESCRIPTION OF THE DRAWINGS

FIG. 1A illustrates a cross-section of an example wafer prior to applying a prior art CMP process.

FIG. 1B illustrates a cross-section of an example wafer including a stop by topology selectivity and a stop by film selectivity.

FIG. 1C illustrates a cross-section of an example wafer including a stop by topology selectivity.

FIGS. 2A-B illustrate example utilizations of an additive and a surfactant.

FIG. 3 illustrates an example topology selectivity CMP process.

FIGS. 4A-B illustrate example planarization results.

FIG. 5 illustrates a graph of BPSG removal rates for various parameters.

FIG. 6 illustrates an example graph of step height v. remaining oxide thickness.

FIG. 7 illustrates an example graph of WIW ranges.

### DETAILED DESCRIPTION OF PREFERRED EMBODIMENTS

The present invention relates to chemical mechanical polishing, and in particular to performing chemical mechanical polishing using slurries. Embodiments of the present invention provide topology and/or film selective chemical mechanical polishing that can be used, by way of example, for cell, poly, STI (shallow trench isolation), ILD (Inter-layer dielectric), or IMD (Inter-metal dielectric) polishing.

In particular, a multi-step CMP process is described wherein a relatively high force, low topology selectivity CMP process is performed first to remove protrusions, and then a relatively low force, high topology selectivity CMP process is performed. The low topology selectivity CMP primarily removes protrusions, while the high topology selectivity CMP is used to achieve a high degree of WIW (With In Wafer) uniformity. For example, a WIW range of 1000 Å or less, or even 500 Å or less, can be achieved using a SAC (self aligned contact) etch process. The topology selective CMP process can be used, by way of example, to polish metal or dielectric layers in multilevel metallization interconnect structures.

Advantageously, the topology selective CMP process removes patterns with high profile variation and height pattern density without causing dishing or over-polishing. Thus, the topology selective CMP process acts as self-planarization process that further provides a height selective insert layer providing a self-stop function.

By way of illustration, when CMP was performed on an example wafer using a conventional slurry, planarization was achieved after approximately 7 KÅ (kilo angstroms) of oxide was removed. By contrast, when CMP was performed on an example wafer using the topology-selective slurry described herein, planarization was achieved after approximately 2.5 KÅ of oxide was removed. In addition, because less slurry is used, borophosphosilicate glass (BPSG) deposition cost can be reduced using the topology-selective slurry.

In addition, because the topology selective CMP process provides a substantially uniform planar surface, a wider window exists for subsequent photo or etch processes. Further, the CMP process described herein can better reduce oxide thickness and so improves the uniformity that results when using a multi-chamber CVD system.

In an example embodiment, a wafer is placed on a wafer carrier or holder and a vacuum is generated to hold the wafer in place. Other techniques can be used to hold the wafer in place. The wafer is rotated relative to a polishing pad while pressure is applied. By way of example, the rotation motion can be rotary, orbital, or linear. The polishing pad is affixed to a platen. The polishing pad is porous to hold the slurry. By way of example, the pad can be fabricated using a polyurethane material or a urethane material. Slurry, stored in a container, is supplied to keep the pad and wafer wet, and to provide reactants to abrade surface non-uniformities, irregularities, protrusions, such as in an oxide layer, and to achieve a desired wafer thickness, uniformity, and planarity.

Thus, for example, in the case of metal, the slurry chemically oxidizes the surface of the metal and then the oxidized metal is mechanically removed by the movement of the polishing pad against the suspended abrasive slurry particles. The slurry can include an abrasive, such as ceria, and can further include fumed silica, de-ionized water, an additive, an alkaline solvent, and a buffer solution. Slurry can be dispensed via a nozzle or otherwise. A stop material, such as nitride, that is harder than the oxide be planarized, can be used to prevent over polishing.

Two slurry abrasive concentrations can be used for the corresponding two steps of CMP. A diluted slurry can be used for the low topology selectivity CMP process. An undiluted slurry or a substantially undiluted slurry can be used for the high topology selectivity CMP process. For example, the slurry dilution can be in the range of 1:0(pure)˜1:10. By way of example, the diluted slurry can be diluted with non-ionized water. In one embodiment, the ratio of slurry to water is approximately 3:7, though other concentration ratios can be used as well, such as ratios within the range of range of 1:0˜1:10 or 2:7 to 5:7. The diluted and substantially undiluted slurries can be separately stored in corresponding separate containers. Optionally, only the substantially undiluted slurry is stored in a container for use, and when the diluted slurry is needed, a portion of the substantially undiluted slurry is diluted for that purpose. By way of example, the abrasive concentration of the diluted slurry can be 70%, 60%, 50%, 40%, or less than that of the undiluted slurry.

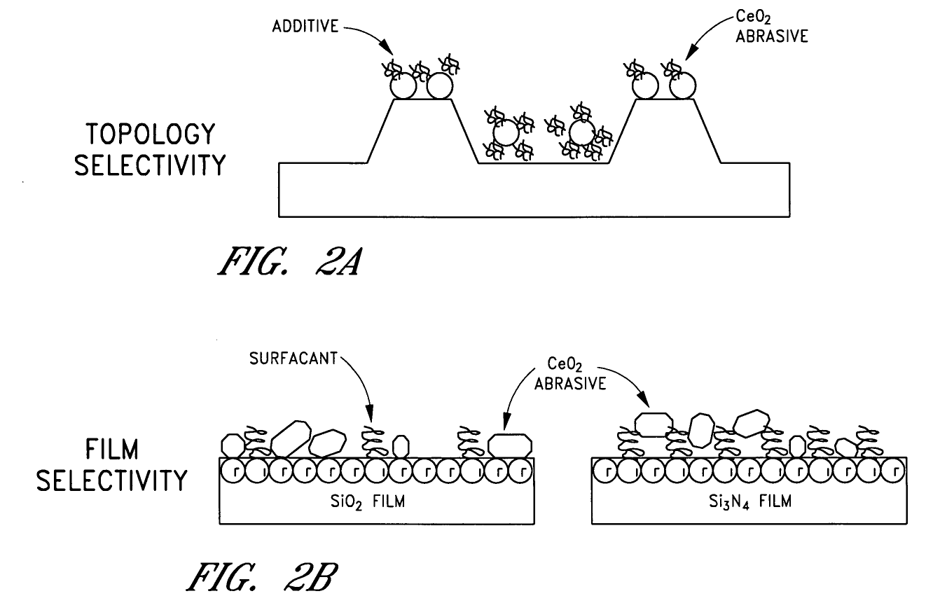

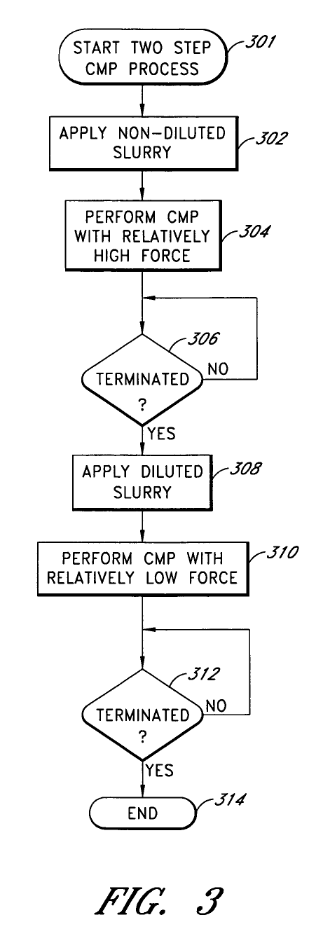

Both the undiluted and diluted slurry can include a ceria-based abrasive, such as a CeO² based abrasive. Other abrasives, such as SiO2, CeO2, ZrO2, Al2O3, or Mn2O3, with or without surface coating, can be used. With respect to topology selectivity, referring to FIG. 2A, the ceria is optionally wrapped up in an additive, such as NH₄₊, Cs₊ and Ba₃₊, or alkaline, carbohydrates, or polyacrylate, to enhance the topology selectivity. The additive can be selected based on the type of planarization or CMP being performed, such as on whether Cell/Poly/ILD/IMD CMP is being performed, or whether STI CMP is being performed on an oxide or SiN film The additive will be substantially eliminated and the ceria or other abrasive will be exposed to polish the wafer.

The addition to the slurry of an appropriate wetting agent or surfactant, such as one or more of an alkaline, carbohydrates, polyacrylate, anionic, cationic, nonionic, or an amphoteric surfactant can enhance CMP film selectivity, while providing adequate sedimentation stability and a high zeta potential at the appropriate pH value, and can reduce WIWNU (within-wafer-non-uniformity). With respect to film selectivity, referring to FIG. 2B, the surfactant can be selected based on whether SiO₂ or SiN₄ film is being polished.

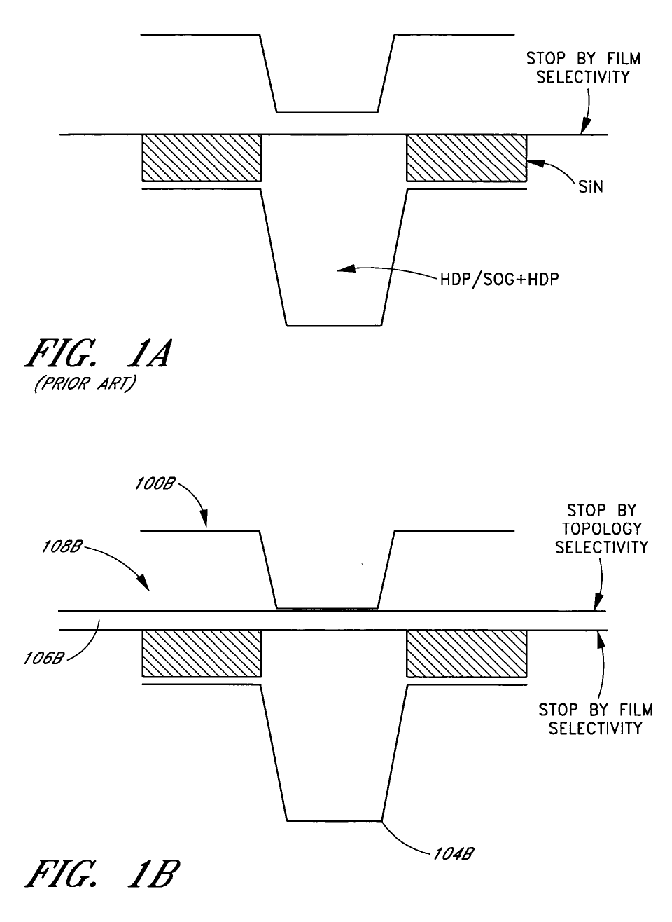

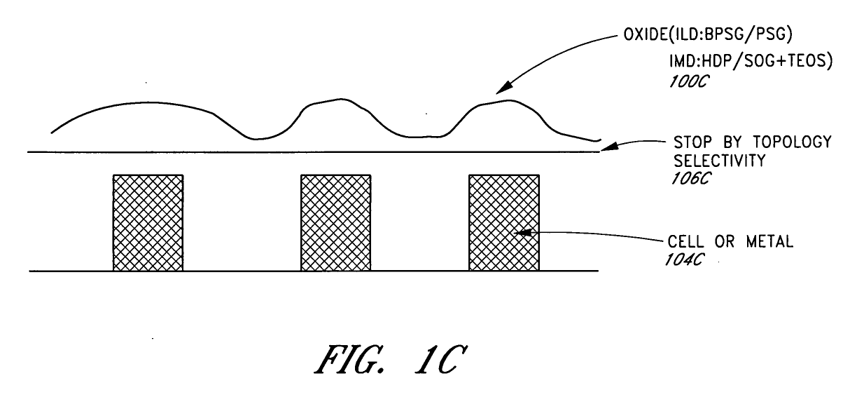

As shown in FIG. 1B, in one embodiment, an example semiconductor wafer 100B includes a stop by topology selectivity and a stop by film selectivity. The semiconductor wafer 100B includes a silicon substrate 102B with a wide trench 104B formed thereon, a polishing stop layer 106B formed outside the trench 104B, and a trench-fill dielectric 108B filling the trench 104B and covering the polishing stop layer 106B. The trench-fill dielectric 108B can be for example, silicon dioxide, formed using a high density plasma (HDP) vapor deposition process or a spin-on-glass (SOG) process, by way of example. The polishing stop layer 106B can be, by way of example, a silicon nitride layer.

As shown in FIG. 1C, in another embodiment, an example semiconductor wafer includes a stop by topology selectivity. Includes a stop by topology selectivity 106C overlaying metal or cells 104C. The stop 106C is overlaid by an oxide layer (e.g., an ILD: BPSG/PSG or IMD: HDP/SOG+TEOS(Tetra-ethoxysilane)).

FIG. 3 illustrates an example topology selectivity CMP process that can be applied to a semiconductor wafer, such at the example semiconductor in FIG. 1A. At state 301, a two step topology selective CMP process is initiated by placing a carrier mounted semiconductor wafer face-down on a polishing pad which is fixedly attached to a rotatable table or platen. Optionally, still additional CMP steps can be performed beyond the two steps described herein.

At state 302, the diluted CeO₂ (or other abrasive) slurry is applied to the polishing pad. The slurry can be sprayed on or otherwise deposited on the polishing pad. The slurry forms a slurry layer at the interface between the polishing pad and the wafer.

At state 304, a chemical mechanical polishing process is performed using the diluted CeO₂ slurry to clear the wafer topology with a high removal rate. Protruding features of the semiconductor wafer are positioned such that they contact the slurry on the polishing pad. By way of example, the polishing pad can be manufactured from polyurethane or polyurethane-impregnated polyester felts. The slurry can further include fumed silica {e.g., SiO2, CeO2, ZrO2, Al2O3, or Mn2O3, with or without surface coating}, de-ionized water, an additive, an alkaline solvent, and a buffer solution. The pH of the diluted slurry is in the range of 3-12, by way of example. The polishing pad and semiconductor wafer may be rotated or otherwise moved relative to each other (e.g., at 50-140 RPM).

The CMP is performed with a relatively high down force, such as within the range of 5-8 psi, thereby providing relatively less topology selectivity with a relatively high removal rate. By way of example, the down force can be created by one or more of a backpressure applied to the rotating wafer and a down force applied to the polishing pad. The diluted slurry initiates the polishing process by chemically reacting with the wafer surface material being polished. By way of example, the surface can be an SiO₂, Si₃N₄, phosphosilicate glass, borophosphosilicate glass, or a fluorinated silicate glass film or layer. The movement of the polishing pad relative to the wafer causes the slurry abrasive particles to physically strip the reacted surface material from the wafer. Wafer protrusions are thereby substantially polished and planarized.

At state 306, a determination is made to terminate the high down force CMP when a desired endpoint is reached or a predetermined amount of time has elapsed. By way of example, the amount of time can be selected based on one or more parameters, such as the thickness of the polished silicate film and the composition of the film.

At state 308, the undiluted or substantially undiluted slurry is applied to the pad. In this example, the pH of the undiluted slurry is in the range of 3-12. At state 310, a chemical mechanical polishing process is performed using the undiluted CeO₂ slurry to achieve the desired WIW uniformity. The CMP is performed with a relatively low down force, thereby providing relatively greater topology selectivity with a relatively lower removal rate. At state 312, a determination is made to terminate the low down force CMP based on the desired endpoint or based on the elapsed time.

The foregoing process can advantageously reduce CMP time by approximately 33% or more, and can reduce the amount of slurry used by approximately 33% or more as compared to the amount of slurry used in many conventional CMP processes. Further, the CMP process described herein can reduce or eliminate the problem encountered with some multi-chamber CVD systems with non-symmetrical topology that may polish edges faster than other areas.

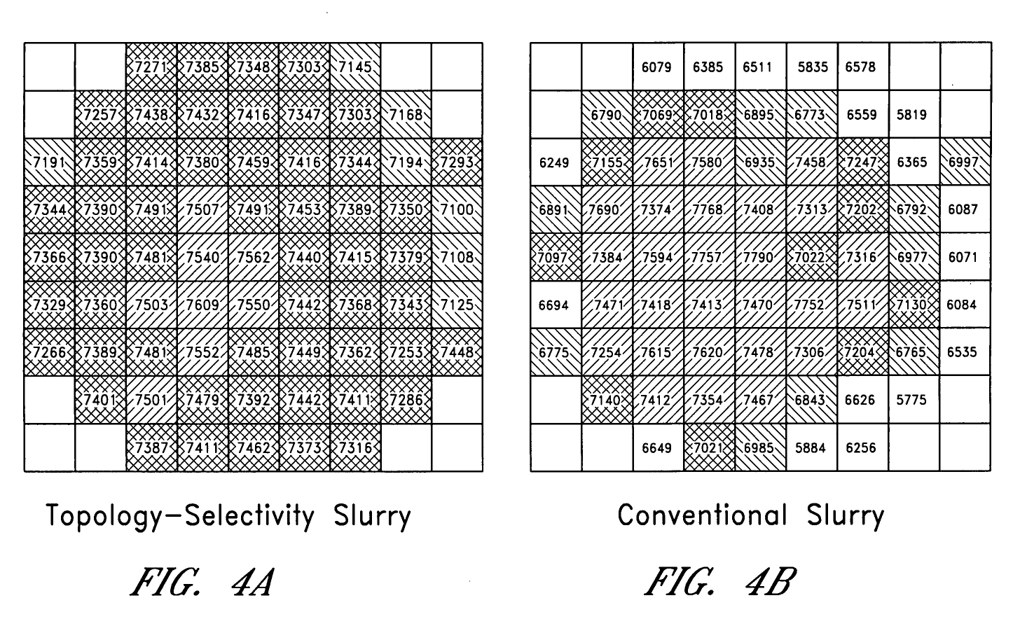

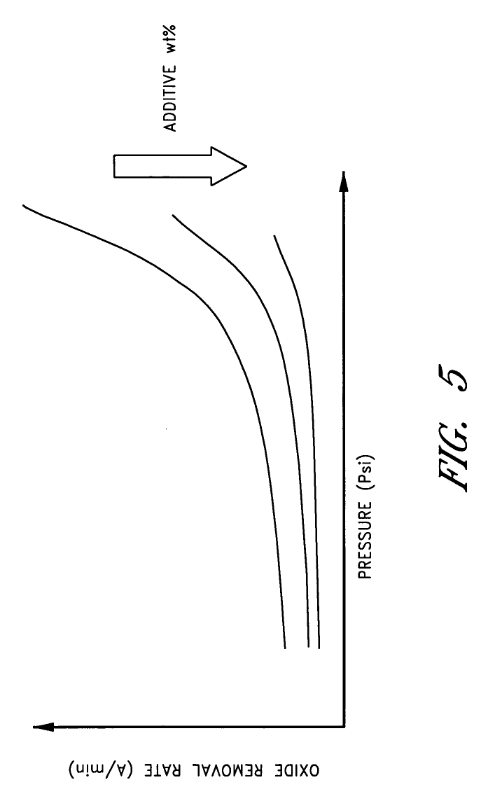

By way of example, using the process described above, a wafer edge step height of approximately 720 Å (angstroms) is achieved with an oxide removal of approximately 2 kA. FIG. 4B illustrates the example planarization after the two step CMP process described herein using topology selective slurry. FIG. 4A illustrates the planarization after a conventional CMP process using a conventional slurry. Utilizing the topology selectivity slurry, there are seven areas having a height greater than 7500 Å, with the remaining areas having heights of less than 7500 Å, as compared to twenty seven areas having a height greater than 7500 Å when a conventional slurry was utilized.

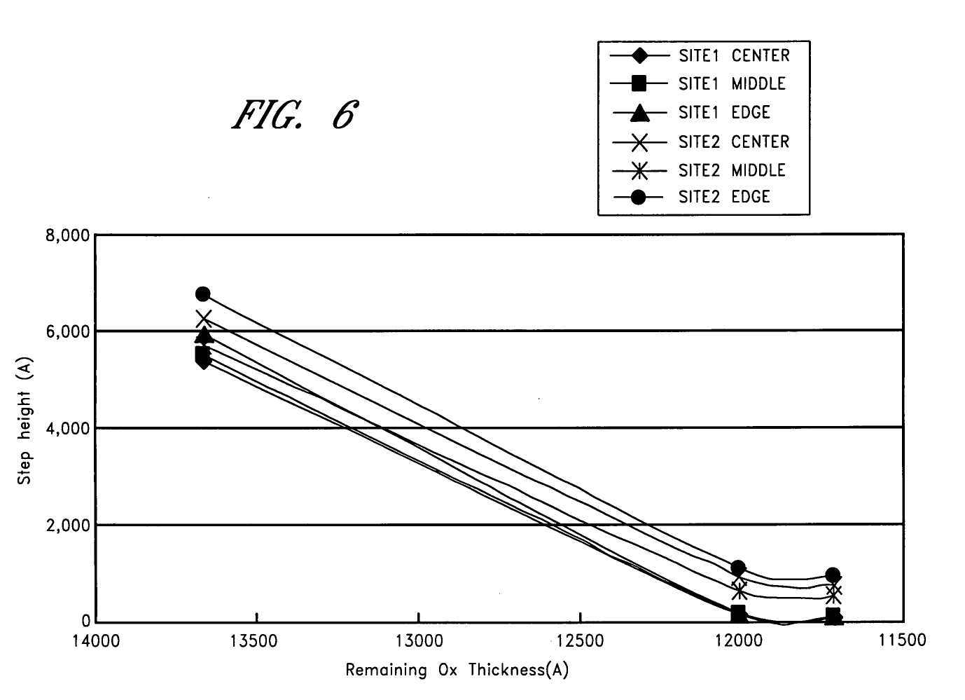

FIG. 5 illustrates a graph of BPSG removal rate v. pressure for various different additive concentrations utilizing the undiluted topology selective slurry. As illustrated, the oxide removal rate increases with an increase in pressure and with an increase in the additive percentage. By way of example, and not limitation, the pressure can be within the range of approximately 2 psi to 5 psi, and the additive content can be within a range of approximately 0.15 to 1.00. In this example, and the resulting BPSG removal rate can be within the range of approximately 300 Å/minute to approximately 3700 Å/minute. Other ranges can be used as well, and other removal rates can be achieved.

In particular, in the illustrated example, the BPSG removal rate with an additive content of 0.15 wt % is approximately 550 Å/minute with a pressure of 2 psi, and the removal rate is approximately 2200 Å/minute, with a pressure of 4 psi. With an additive content of 0.25, the BPSG removal rate is approximately 500 Å/minute with a pressure of 2 psi, and the removal rate is approximately 3700 Å/minute, with a pressure of 5 psi. With an additive content of 0.50, the BPSG removal rate is approximately 400 Å/minute with a pressure of 2 psi, and the removal rate is approximately 1500 Å/minute, with a pressure of 5 psi. With an additive content of 1, the BPSG removal rate is approximately 300 Å/minute with a pressure of 2 psi, and the removal rate is approximately 850 Å/minute, with a pressure of 5 psi.

FIG. 6 illustrates an example graph of step height v. remaining oxide thickness at various locations after the two step CMP process is applied utilizing the topology selective slurry. As illustrated, in this example, the key center step height varies from about 7000 Å with a remaining oxide thickness of about 13500 Å, to about 720 Å with a remaining oxide thickness of about 11700 Å.

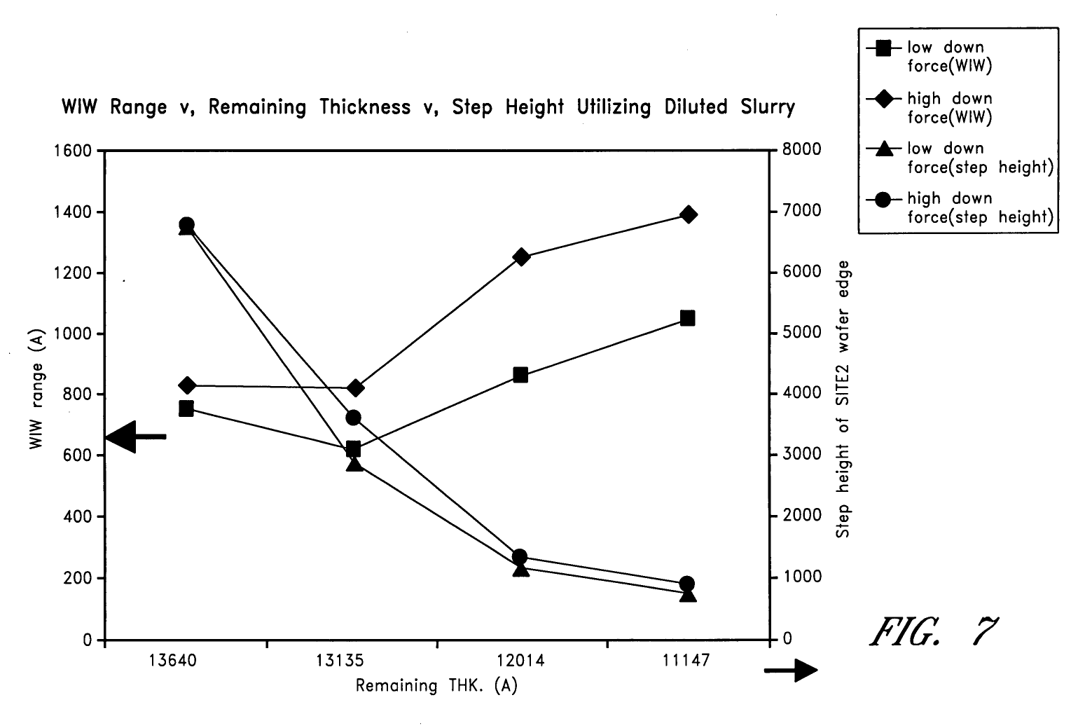

FIG. 7 illustrates an example graph of WIW range v. remaining thickness and v. step height of the wafer edge for the low down force CMP and the high down force CMP.

As described herein, the topology and/or film selectivity chemical mechanical polishing can be used, by way of example, for cell, poly, STI (shallow trench isolation), ILD (Inter-layer dielectric), or IMD (Inter-metal dielectric) polishing.

The foregoing processes can be used with a wide variety of semiconductor applications, including memory circuits and the like.

Those of ordinary skill in the art will appreciate that the methods and designs described above have additional applications, and that the relevant applications are not limited to those specifically recited above. Also, the present invention can be embodied in other specific forms without departing from the characteristics as described herein. The embodiments described above are to be considered as illustrative only, and not.

What is claimed is:

1. A method of performing chemical mechanical polishing (CMP), the method comprising:
applying a substantially undiluted slurry to a polishing pad;
performing a first CMP process with the substantially undiluted slurry on a semiconductor wafer using a first amount of pressure;
terminating the first CMP process;
applying a diluted slurry to the polishing pad;
performing a second CMP process with the diluted slurry on the semiconductor wafer using a second amount of pressure, wherein the second amount of pressure is less than the first amount of pressure; and
terminating the second CMP process.

2. The method as defined in claim 1, wherein the diluted and substantially undiluted slurry include ceria.

3. The method as defined in claim 1, wherein the first and second CMP processes can be used for cell, poly, STI (shallow trench isolation), ILD (Inter-layer dielectric), and IMD (Inter-metal dielectric) polishing.

4. The method as defined in claim 1, wherein the diluted and substantially undiluted slurry include an additive.

5. The method as defined in claim 1, wherein the substantially undiluted slurry includes an additive with a concentration percentage within the range of 0.15 and 1.00.

6. The method as defined in claim 1, wherein the diluted and substantially undiluted slurry include a surfactant.

7. The method as defined in claim 1, wherein the first CMP process removes protrusions and the second CMP process provides a desired WIW (With In Wafer) uniformity.

8. The method as defined in claim 1, wherein the first and second CMP processes provides a WIW (With In Wafer) range of no greater than 1000 Å.

9. The method as defined in claim 1, wherein the first and second CMP processes provides a WIW (With In Wafer) range of no greater than 500 Å.

10. The method as defined in claim 1, wherein the first and second CMP processes are performed on an SiO₂ film.

11. The method as defined in claim 1, wherein the first and second CMP processes are performed on an Si₃N₄ film.

12. The method as defined in claim 1, wherein the first and second CMP processes are performed on at least one of phosphosilicate glass (PSG), borophosphosilicate glass (BPSG), or a fluorinated silicate glass (FSG).

13. The method as defined in claim 1, wherein the diluted slurry has a ratio of slurry to dilution medium within the range of 2:7 to 5:7.

14. The method as defined in claim 1, wherein the diluted slurry has a ratio of slurry to dilution medium of approximately 3:7.

15. The method as defined in claim 1, wherein the diluted slurry is diluted using de-ionized water.

16. The method as defined in claim 1, wherein the first CMP process is performed with a pressure within the approximate range of 2 psi to 5 psi.

17. The method as defined in claim 1, wherein the first CMP process provides a borophosphosilicate glass removal rate within the range of approximately 300 Å/minute to approximately 3700 Å/minute.

18. The method as defined in claim 1, wherein the first CMP process provides a borophosphosilicate glass removal rate within the range of approximately 2200 Å/minute to approximately 3700 Å/minute.

19. The method as defined in claim 1, wherein the first and second CMP processes do not cause dishing or over-polishing.

20. The method as defined in claim 1, wherein the diluted slurry is stored in a first container and the substantially undiluted slurry is stored in a second container.

21. A method of performing chemical mechanical polishing (CMT), the method comprising:
providing a semiconductor wafer having a first film;
performing a first CMP process on a semiconductor wafer first film using a first slurry having a first abrasive concentration and applying first amount of pressure; and
performing a second CMP process on the semiconductor wafer first film using a second slurry having a second abrasive concentration no greater than 70% of the first concentration, and applying a second amount of pressure, wherein the second amount of pressure is less than the first amount of pressure.

22. The method as defined in claim 21, wherein the first and second slurries include CeO₂.

23. The method as defined in claim 21, wherein the first and second slurries include at least a first additive.

24. The method as defined in claim 21, wherein the second slurry includes de-ionized water, an additive, a solvent, and a buffer solution.

25. The method as defined in claim 21, wherein the first slurry includes an additive with a concentration percentage within the range of 0.15 and 1.00.

26. The method as defined in claim 21, wherein the first and second slurries include a surfactant.

27. The method as defined in claim 21, wherein the first CMP process removes protrusions and the second CMP process provides a desired WIW (With In Wafer) uniformity.

28. The method as defined in claim 21, wherein the first and second CMP processes provides a WIW (With In Wafer) range of no greater than 1000 Å.

29. The method as defined in claim 21, wherein the first and second CMP processes provides a WIW (With In Wafer) range of no greater than 500 Å.

30. The method as defined in claim 21, wherein the first and second CMP processes are performed on an SiO₂ film.

31. The method as defined in claim 21, wherein the first and second CMP processes are performed on an Si₃N₄ film.

32. The method as defined in claim 21, wherein the first and second CMP processes are performed on at least one of phosphosilicate glass (PSG), borophosphosilicate glass (BPSG), or a fluorinated silicate glass (FSG).

33. The method as defined in claim 21, wherein the second concentration is no greater than 60% of the first concentration.

34. The method as defined in claim 21, wherein the second concentration is no greater than 50% of the first concentration.

35. The method as defined in claim 21, wherein the second concentration is no greater than 40% of the first concentration.

36. The method as defined in claim 21, wherein the first CMP process is performed with a pressure within the approximate range of 2 psi to 5 psi.

37. The method as defined in claim 21, wherein the first CMP process provides a borophosphosilicate glass removal rate within the range of approximately 300 Å/minute to approximately 3700 Å/minute.

38. The method as defined in claim 21, wherein the first CMP process provides a borophosphosilicate glass removal rate within the range of approximately 2200 Å/minute to approximately 3700 Å/minute.

39. The method as defined in claim 21, wherein the first and second CMP processes do not cause dishing or over-polishing.

40. The method as defined in claim 21, wherein the first slurry is stored in a first container and the second slurry is stored in a second container.

41. The method as defined in claim 21, wherein the first CMP process is terminated when a desired endpoint is reached.

42. The method as defined in claim 21, wherein the second CMP process is terminated when a predetermined amount of time has elapsed.
